(19) United States
(12) Patent Application Publication
(10) Pub. No.: US 2026/0045902 A1
(43) Pub. Date: Feb. 12, 2026

(54) Floating Inflatable Concentrating Solar Light and Power Supply Uniut C

(71) Applicant: Yonghua Wang, Klamath Falls, OR (US)

(72) Inventor: Yonghua Wang, Klamath Falls, OR (US)

(21) Appl. No.: 18/831,139

(22) Filed: Aug. 12, 2024

(51) Int. Cl. H02S 40/22; H02S 20/00; H02S 40/38

(52) U.S. Cl. CPC H02S 40/22; H02S 20/00; H02S 40/38

(57) ABSTRACT

A floating inflatable concentrating solar light and power supply unit that can concentrate both beam light and diffuse light with high concentration ratio, cogenerate electric power and thermal energy, supply AC power constantly during daytime, and provides illumination during night time comprises: an inflatable domed divergent Fresnel lens and non-imaging solar concentrator based large concentration stationary concentrator filled with helium or hydrogen; a transparent cylinder with its wall covered with displays; at least one LED light or light bulb; a hybrid solar thermal and photovoltaic receiver; at least one thermoelectric module; a thermal energy storage; a battery bank with a electric charger and a charging controller; and a micro inverter. Wherein the transparent cylinder surrounds the inflatable concentrator and the LED lights or light bulb is positioned in between the concentrator and transparent cylinder. The entire system is floating in the sky without occupying land.

### TECHNICAL FIELD

The present disclosure relates generally to solar light and power supply unit, more specifically, to a floating inflatable non-imaging non-tracking stationary concentrator based concentrating solar light and power supply unit with energy storage, micro inverter, and flexible display.

### BACKGROUND

At present, most of solar systems are mounted on ground occupying valuable land on earth. As the exponential growth of human being population, the land on earth can never satisfy the demand of energy from human being by using solar energy. The conflict between the land use for generating power and land uses for other purposes presents a grand challenge in front of solar research scientists and engineers. One of solutions is air floating solar systems which don't occupy land on earth. However, apart from air craft equipped with flat plate photovoltaic panels or thin film solar cells, nobody has ever seen air floating solar systems. The reasons for that are low efficiency, high cost, and heavy weight of conventional solar systems, and there is no good way to lift solar systems.

Street lights, garden lights, lawn lights, or other out-door lights consume paramount of electric power, which at the present most likely comes from fossil fuel. Rather than consuming power, those out-door power users at night are potentially solar power generators in daytime. Actually, the solar lamps are one of the market penetrated solar technologies. However, it is far from the wide-spread adoption of these systems for power generation. Most of solar lamps are based on flat-plate photovoltaic panels, and their lamps and photovoltaic systems are normally separated. This design paradigm is just a simple combination of conventional lamp and photovoltaic panels, which facilitates the manufacture and installation of the system, but is not compact and cost-effective. The conventional flat-plate photovoltaic panel has limited conversion efficiency, and the photovoltaic system and the lamp separately occupy the different areas of the supporting structure. In the conventional solar lamp system, large area expensive semiconductor panels are directly used to collect solar radiation with low energy current density, so the overall cost is inevitably high. Apart from battery storage, the conventional flat plate photovoltaic panel based solar lamp has no other means to store energy.

Relative to the extremely low energy current density of solar radiation, any normal cheap materials such as metal and glass appear to be too expensive to be adopted to realize the extremely low cost of solar collectors. Novel approaches must be created to collect solar radiation. Inflatable solar concentrator is one of such approaches. U.S. Pat. No. 8,074,638 B2 granted to Eric Bryant Cummings (Cummings) disclosed an inflatable solar concentrator balloon method and apparatus. In Cummings's disclosure, a parabolic dish is formed at bottom of the film body of the balloon. This balloon only uses a thin film and a reflective coating to concentrate sunlight and relies on pressure difference between inside and outside of the balloon body to form the geometric shape of the parabola, therefore has a great potential to realize extremely low cost of solar collector. However, parabolic dish is an imaging concentrator which can only concentrate beam sunlight but not diffuse sunlight. Imaging concentrator requires precise geometry shape to concentrate beam light. Inflatable solar concentrator balloon is hard to form and maintain the geometric shape of parabola. In addition, imaging concentrator requires precision solar tracker, which significantly increase the system cost and system complexity, to concentrate beam light.

Unlike imaging concentrator, non-imaging inflatable solar concentrator can concentrate both beam and diffuse sunlight simultaneously. Non-imaging inflatable concentrator does not need to maintain its geometric shape precisely. Non-imaging inflatable concentrator has potential to waive the requirement of tracker.

Relative to imaging inflatable solar concentrator balloon, the biggest drawback of the non-imaging solar concentrator balloon is low concentration ratio. The concentration ratio of the CPC is determined by the acceptance half angle θ_{c}. The larger the acceptance half angle θ_{c}, the smaller the concentration ratio of the CPC.

$$f = {a}^{′} ( 1 + sin {θ}_{c} ) \qquad ( 1 - 1 )$$

$$a = \frac{{a}^{′}}{sin {θ}_{c}} \qquad ( 1 - 2 )$$

$$h = \frac{f cos {θ}_{c}}{{sin}^{2} {θ}_{c}} \qquad ( 1 - 3 )$$

$$C = \frac{a}{{a}^{′}} = \frac{1}{sin {θ}_{c}} \qquad ( 1 - 4 )$$

$${C}_{3 d} = {( \frac{a}{{a}^{′}} )}^{2} = \frac{1}{{sin}^{2} {θ}_{c}} \qquad ( 1 - 5 )$$

Two dimensional trough type of CPC is formed by combing two halves of parabolic curve and three dimensional CPC is just the rotational version of the combination of two halves of parabolic curve. Equation 1-1 gives formula to calculate the focal length f of the parabolic curve by using the diameter a′ of the output aperture of the CPC and the acceptance half angle θ_{c} of the CPC. Equation 1-2 gives relationship between the diameter a′ of the output aperture and the diameter a of the input aperture of the CPC. Equation 1-3 gives relationship between the height h of the CPC and f and θ_{c}. Equation 1-4 and 1-5 provides formulas for calculating the concentration ratios of two dimensional and three dimensional CPC respectively.

For large θ_{c}, the concentration ratio is a small number. For instance, with θ_{c}=30°, the concentration ratio is 2 (John Duffie & William Beckman, Solar Engineering of Thermal Processes, 4th Edition, pp 337-344, 2013). For concentration ratio only 10, θ_{c} must be as small as 6°. Ideally for day-long non-tracking concentration, the θ_{c} should be at least 75°. For practical application, the concentration ratio should be several hundreds and even more. Therefore, the grand challenge for practical non-imaging concentrator is that it should have small acceptance half-angle for high concentration ratio, but in the mean time has large acceptance half-angle for stationary concentration.

The objectives of the present invention is to provide a design paradigm of floating inflatable concentrating solar light and power supply unit which can concentrate both beam sunlight and diffuse sunlight with high concentration ratio without tracking to cogenerate electricity and thermal energy, store the cogenerated electricity and thermal energy, and supply AC power constantly during daytime, and provide illumination and display during night time.

### SUMMARY

According to the present invention, the floating inflatable concentrating solar light and power supply unit comprises: 1) a inflatable divergent Fresnel lens and non-imaging concentrator enabled non-imaging non-tracking concentrator filled with helium or hydrogen; 2) a transparent cylinder with flexible displays; 3) a hybrid solar thermal and photovoltaic receiver; 4) a LED or light bulb illumination subsystem; 5) a battery bank; 6) a thermoelectric energy storage subsystem; 7) a electric charger and charging controller subsystem; 8) and a micro inverter. Wherein, the divergent Fresnel lens and non-imaging concentrator enabled non-imaging non-tracking concentrator is surrounded with the transparent cylinder with displays at the bottom of the concentrator; the hybrid solar thermal and photovoltaic receiver is installed beneath the inflatable divergent Fresnel lens and non-imaging concentrator enabled non-imaging non-tracking concentrator; the LED or light bulb illumination subsystem is installed in the space between the divergent Fresnel lens and non-imaging concentrator enabled non-imaging non-tracking concentrator and the transparent cylinder with displays. When in operation, incident sunlight is firstly refracted by the domed divergent Fresnel lens cover on the top of the inflatable divergent Fresnel lens and non-imaging concentrator enabled non-imaging non-tracking concentrator and then concentrated by the CPC of the inflatable divergent Fresnel lens and non-imaging concentrator enabled non-imaging non-tracking concentrator to the receiver during daytime to generate electricity and thermal energy. The cogenerated electricity is stored into the battery bank and the cogenerated thermal energy is stored into the thermoelectric energy storage subsystem during daytime. During night, the energy stored in battery bank and thermoelectric storage subsystem is drained to light the LEDs or light bulbs. Wherein, the interior surface of the inflatable divergent Fresnel lens and non-imaging concentrator enabled non-imaging non-tracking concentrator concentrates sunlight during daytime, while the exterior surface of the inflatable divergent Fresnel lens and non-imaging concentrator enabled non-imaging non-tracking concentrator reflects the light emitted by LEDs or light bulbs during night. The entire system serves as an AC power supply by draining the energy from the battery bank and thermoelectric energy storage subsystem and outputting AC power through the micro inverter.

The floating inflatable concentrating solar light and power supply unit of the present invention provides an approach to dramatically increase the conversion efficiency, substantially decrease the cost, and effectively eliminate the intermittence of solar systems with simplicity of flat plate photovoltaic panels. This invention provides possibilities to cogenerate electricity and thermal energy with high temperature to increase total conversion efficiency of solar systems, and the cogenerated high temperature thermal energy can be stored by employing the thermoelectric energy storage subsystem. The configuration of the inflatable concentrating solar light and power supply unit dramatically reduces the semiconductor area needed for solar radiation collection and conversion, and therefore significantly reduce the cost of the system. The present invention synergistically combines the Concentrating Solar Power (CSP) system with lighting system to form a system generating power during daytime and illuminating space during night time. Unlike flat plate photovoltaic panel, which is just a system component, the apparatus of this present invention is a complete system integrated with energy storage, charger, and micro inverter, which can be easily commercialized into a complete product. The present invention provides a non-imaging and non-tracking optics which not only ensures concentration of both diffuse light and direct light, but also high concentration ratio under high acceptance half-angles. The floating inflatable concentrating solar light and power supply unit is lifted in air by the lighter than air gases such as helium and hydrogen filled in the inflatable domed divergent Fresnel lens and non-imaging concentrator enabled stationary concentrator balloon.

Further aspects and advantages of the present invention will become apparent upon consideration of the following description thereof, reference being made of the following drawing.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 is a cross section view of the floating inflatable concentrating solar light and power supply unit, wherein, a floating inflatable non-imaging non-tracking high concentration solar concentrator filled with helium or hydrogen is surrounded by a transparent cylinder with its wall covered with flexible electronic displays, at least one LED light or light bulb is placed in the space between the solar concentrator and the transparent cylinder.

FIG. 2 is an over view of the floating inflatable concentrating solar light and power supply unit.

FIG. 3 is the overview of the non-imaging non-tracking solar concentrator, wherein, the bottom of the concentrator is a 3D CPC, and the top of the concentrator is a flexible domed divergent Fresnel lens.

FIG. 4 is an indication of work principle of non-imaging solar concentrator which can concentrate not only beam light, but also diffuse light.

FIG. 5 is an indication of work principle of non-imaging non-tracking solar concentrator which can concentrate both beam light and diffuse light with high concentration ratio.

FIG. 6 is a schematic indication of the entire system of the floating inflatable concentrating solar light and power supply unit, wherein, apart from the concentrating solar light, the system also includes a receiver to cogenerate electricity and thermal energy, a thermoelectric module to raise temperature of the cogenerated thermal energy and convert the stored thermal energy back into electricity, a thermal energy storage, a battery bank with a charger and charging controller, and a micro inverter to output AC power.

### DETAILED DESCRIPTION

Reference will now be made in detail to the present exemplary embodiments, examples of which are illustrated in the accompanying drawings. Wherever possible, the same reference numbers will be used throughout the drawings to refer to the same or like parts.

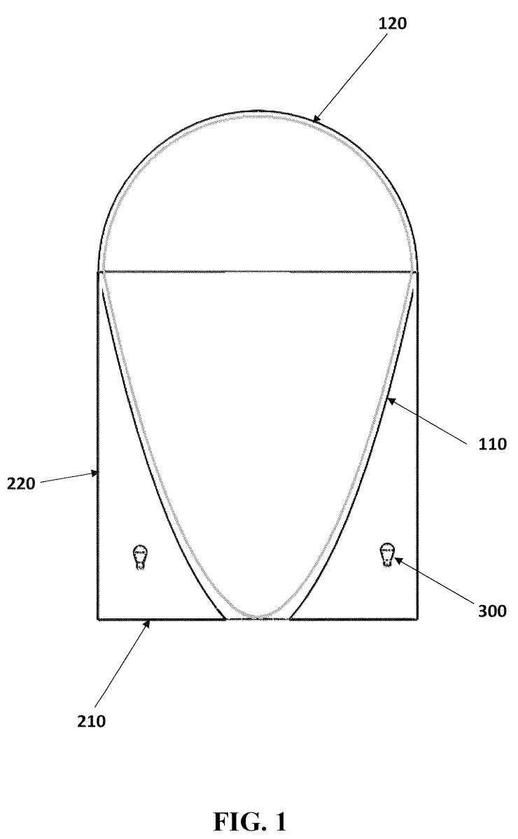

Referring to FIG. 1, the floating inflatable concentrating solar light and power supply unit comprises a inflatable non-imaging non-tracking concentrator made of a bottom part the CPC 110 with its interior surface coated with reflective materials and a top part the flexible domed divergent Fresnel lens 120, and filled with helium or hydrogen, a transparent cylinder with its wall covered with displays 220 and its transparent bottom cover 210, and the lights 300 which can be either LEDs or light bulbs. When in operation, the incident light including beam light and diffuse light is firstly refracted by the flexible domed divergent Fresnel lens 120, and then concentrated by the CPC 110 to receiver to cogenerate electricity and thermal energy during daytime. During night time, the light emitted by the lights 300 is reflected out by the back side of the reflective coating coated on the interior surface of the CPC 110.

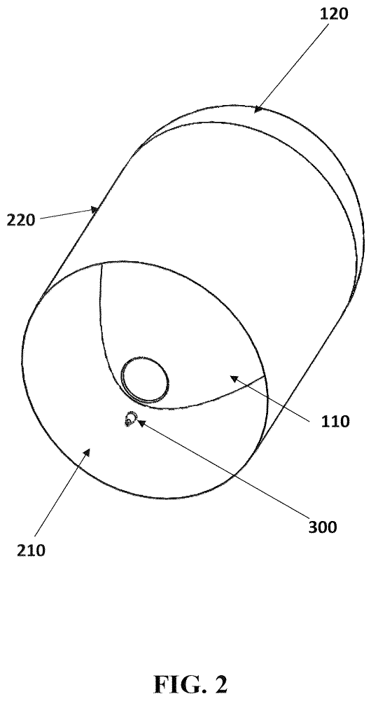

Referring to FIG. 2, there is space between the CPC 110 and transparent cylinder 220 for lights.

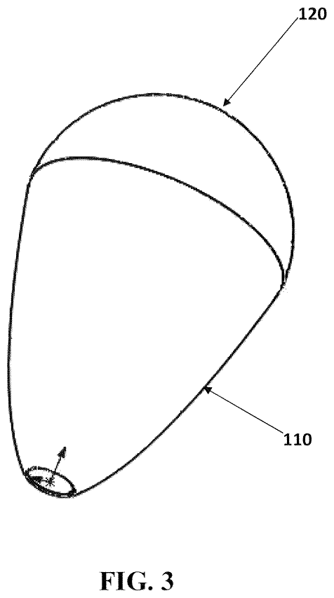

Referring to FIG. 3, the floating inflatable non-imaging non-tracking solar concentrator is made of a bottom part the CPC 110 and a top part the flexible domed divergent Fresnel lens 120.

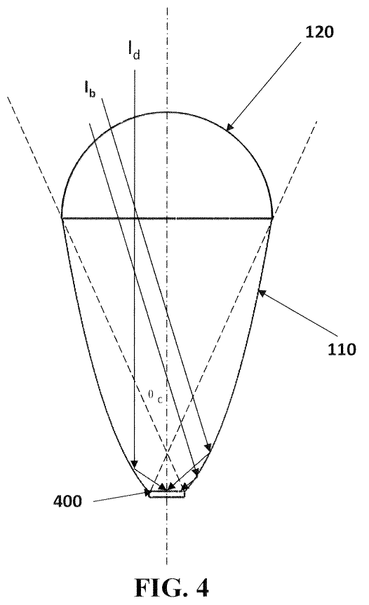

Referring to FIG. 4, both beam light I_{b} and diffuse light I_{d} are concentrated to receiver located at the output aperture of the CPC 110, as long as the incident angles of the I_{b} and I_{d} are smaller than the acceptance half-angle θ_{c} of the CPC.

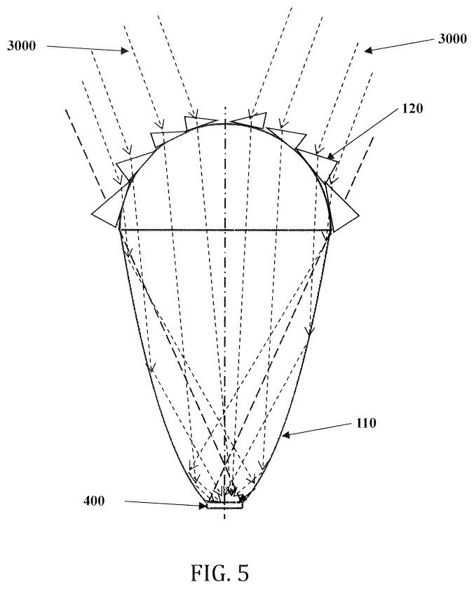

Referring to FIG. 5, in the present invention, a flexible domed divergent Fresnel lens 120 is added onto the transparent cover of the inflatable CPC 110 with small acceptance half-angle, so that the oblique incident light is refracted to fall in the small acceptance half-angle. During a diurnal day, the morning light is refracted by the left-hand side of the flexible domed divergent Fresnel lens 120, the afternoon light is refracted by the right-hand side of the domed divergent Fresnel lens 120, and the noon light is affected little.

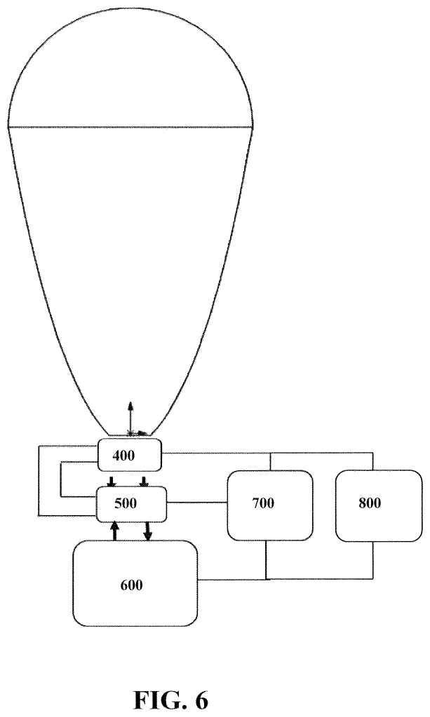

Referring to FIG. 6, during daytime, after the concentrating solar light, the incident sunlight is concentrated to a receiver 400 that cogenerates electricity and thermal energy, portion of the cogenerated electricity is stored in a battery storage 700, and other portion of the cogenerated electricity is used to power a thermoelectric module 500 to raise the temperature of the cogenerated thermal energy, the cogenerated thermal energy is stored in a thermal energy storage 600 for the thermoelectric module to turn back to electricity during night time. The electricity stored in the battery bank 700 is output in AC power through a micro inverter 800.

From the description above, a number of advantages of the floating inflatable concentrating solar light and power supply unit become evident. The entire system is floating in sky without occupying land. The display provides a platform for advertisement. The stationary concentrator capable of concentrating sunlight with high concentration ratio completely eliminates the need of tracking system and makes it possible to dramatically reduce the cost of solar system. The synergistically combination of stationary solar concentrator and lighting units makes it a CSP system during daytime and a solar light during night time. The system cogenerates electricity and thermal energy and the cogenerated thermal energy is raised in temperature for thermoelectric energy storage through thermoelectric module. This feature provides an approach to realize large scale energy storage of solar energy. This system provides a platform to integrate energy storage, thermoelectric device, and micro inverter to make it a constant power generation apparatus. This system consolidates the powerful feature of concentrating systems and simplicity of flat plate photovoltaic panels. This system provides an unprecedented opportunity to incorporate the systems into urban street light systems and rural agrivoltaic systems. Since the cogenerated electricity is used to power the thermoelectric module, the interaction of the thermal generation part and electric generation part is built up to enhance power output.

In the preceding specification, various preferred embodiments have been described with reference to the accompanying drawings. It will, however, be evident that various other modifications and changes may be made thereto, and additional embodiments may be implemented, without departing from the broader scope of the invention as set forth in the claims that follow. The specification and drawings are accordingly to be regarded in an illustrative rather than restrictive sense.

Other embodiments of the invention will be apparent to those skilled in the art from consideration of the specification and practice of the invention disclosed herein. It is intended that the specification and examples be considered as exemplary only, with the true scope and spirit of the invention being indicated by the following claims.

I claim:

1. A floating inflatable concentrating solar light and power supply unit comprises: 1) an inflatable domed divergent Fresnel lens and non-imaging solar concentrator based large concentration stationary concentrator filled with helium or hydrogen; 2) a transparent cylinder with its wall covered with display; 3) at least one LED light or light bulb; 4) a hybrid solar thermal and photovoltaic receiver; 5) at least one thermoelectric module; 6) a thermal energy storage; 7) a battery bank with a electric charger and a charging controller; 8) and a micro inverter; wherein the transparent cylinder surround the floating inflatable domed divergent Fresnel lens and non-imaging solar concentrator based large concentration stationary concentrator; the LED lights or light bulbs are positioned in the space between the floating inflatable domed divergent Fresnel lens and non-imaging solar concentrator based large concentration stationary concentrator and the transparent cylinder; the hybrid solar thermal and photovoltaic receiver is place beneath the output aperture of the floating inflatable domed divergent Fresnel lens and non-imaging solar concentrator based large concentration stationary concentrator; the thermoelectric modules are attached to the backside of the hybrid solar thermal and photovoltaic receiver; the photovoltaic portion of the hybrid solar thermal and photovoltaic receiver is electrically connected to the thermoelectric modules; the thermoelectric modules are thermally coupled to the thermal storage; thermoelectric modules are electrically connected to the battery bank through the electric charger and charging controller; the photovoltaic portion of the hybrid solar thermal and photovoltaic receiver is electrically connected to the battery bank through the electric charger and charging controller; the micro inverter is electrically connected to the battery bank; the LED lights or light bulbs are electrically connected to the battery bank through a controller; wherein when in operation, during daytime, oblique incident sunlight including beam light and diffuse light is firstly refracted by the domed divergent Fresnel lens on top of the floating inflatable domed divergent Fresnel lens and non-imaging solar concentrator based large concentration stationary concentrator, and then concentrated by the CPC at the bottom of the floating inflatable domed divergent Fresnel lens and non-imaging solar concentrator based large concentration stationary concentrator onto the hybrid solar thermal and photovoltaic receiver; the receiver cogenerates electricity and thermal energy; a portion of the cogenerated electricity is used to power the thermoelectric modules; another portion of the cogenerated electricity is used to charge the battery bank; the cogenerated thermal energy is raised in temperature and stored into the thermal storage through the thermoelectric modules; the battery bank is used to output AC power through the micro inverter; during night time, the stored thermal energy in thermal storage is extracted to generate electricity to charge the battery bank; the battery bank is used to power the LEDs or light bulbs.

2. The floating inflatable domed divergent Fresnel lens and non-imaging solar concentrator based large concentration stationary concentrator of claim 1 is made of a flexible domed divergent Fresnel lens on the top and a non-imaging solar concentrator CPC at the bottom; wherein the CPC formed with a sealed bag made of flexible membrane with its interior surface coated with reflective coating and the flexible domed divergent Fresnel lens is either molded on the top of the CPC or formed by adding a separate flexible domed divergent Fresnel lens on top transparent cover of CPC.
